(19) United States
(12) Patent Application Publication
(10) Pub. No.: US 2009/0191723 A1
(43) Pub. Date: Jul. 30, 2009

(54) METHOD OF PERFORMING LITHOGRAPHIC PROCESSES

(76) Inventors: Chi-Ching Huang, Tainan County (TW); Tzu-Ching Yen, Kaohsiung City (TW); Shih-Chieh Lo, Tainan City (TW); Wen-Tsung Wu, Kaohsiung County (TW)

Correspondence Address: NORTH AMERICA INTELLECTUAL PROPERTY CORPORATION, P.O. BOX 506, MERRIFIELD, VA, 22116, US

(21) Appl. No.: 12/022,161

(22) Filed: Jan. 30, 2008

(51) Int. Cl. H01L 21/02

(52) U.S. Cl. 438/795; 257/E21.002

(57) ABSTRACT

Method of performing lithographic processes on a wafer in a lithographic apparatus having multiple stages. First, a lithographic apparatus including a first wafer chuck and a second wafer chuck is provided. Subsequently, a cassette including a plurality of wafers is provided in the lithographic apparatus, and each wafer has a wafer identification. Thereafter, the first wafer chuck is set for holding the wafers having odd wafer identifications, and the second wafer chuck is set for holding the wafers having even wafer identifications. Next, a first lithographic process is performed on each wafer by the lithographic apparatus.

### BACKGROUND OF THE INVENTION

1. Field of the Invention

The present invention relates to a method of performing lithographic processes, and more particularly, to a method of performing lithographic processes on a wafer in a lithographic apparatus having multiple stages.

2. Description of the Prior Art

Lithographic technologies are key technologies to affect the critical dimensions in the semiconductor processes; and overlay accuracies are key factors to control the lithographic technology. Most of electric circuit patterns are formed by transferring the patterns of masks to photoresists in the lithographic processes, and thereafter transferring the patterns of photoresists to the material layers of a wafer in the etching processes. Thus, the patterns of masks must be disposed in exact positions in every etching process for forming electric circuit patterns in each material layer. Otherwise, the electric circuit pattern in one material layer may not cooperate with the underlying electric circuit pattern, and the formed electric circuit therefore fails.

Taking the general integrated circuit as an example, the acceptable overlay inaccuracies among the STI structure, the gate and the contact plugs of a MOS transistor are smaller than those among other semiconductor elements. For instance, the acceptable overlay inaccuracy between the STI structure and the gate, and the acceptable overlay inaccuracy between the contact plugs and the gate are usually less than 15 nanometers (nm) for 65 nm process, while the acceptable overlay inaccuracy between the STI structure and the contact plugs of a MOS transistor is usually less than 25 nm. Thus, the overlay accuracies of these corresponding lithographic processes are especially important. Please refer to FIG. 1, which is a schematic diagram showing a traditional MOS transistor. In the following description, an N-type MOS transistor is considered. As shown in FIG. 1, a MOS transistor 20 is formed on a silicon substrate 10 of a semiconductor chip. A photoresist layer (not shown in the drawing) is first coated on the surface of the silicon substrate 10. Subsequently, a pattern of shallow trench isolation (STI) structure 30 is defined in the photoresist layer by a lithography process. Next, an etching process is performed to form at least an opening of the STI structure 30 in the silicon substrate 10. Thereafter, the opening of the STI structure 30 is filled up with insulating materials to form at least an STI structure 30. The STI structure 30 is used to define at least an active area (AA) 32 for the MOS transistor 20. P-type dopants are next used to dope the silicon substrate 10. A thermal process is performed to drive the dopants into the silicon substrate 10 so as to form a P-well 12. A thermal oxidation process and a thin film process are then performed on the silicon substrate 10 to form a silicon dioxide layer and a doped polysilicon layer.

Afterward, another photoresist layer (not shown) is coated onto the surface of the silicon substrate 10, and another photolithographic process is performed on the photoresist layer to define the pattern of a gate 26. Then another etching process is performed to form a gate oxide layer 22 and a gate electrode 24 of the gate 26. The photoresist layer is then stripped. An ion implantation process is performed to form lightly doped drains (LDD) 14, adjacent to the lateral sides of the gate 26 of the MOS transistor 20. A silicon nitride layer (not shown) is thereafter deposited on the surface of the silicon substrate 10, and an anisotropic dry etching process is furthermore performed to remove parts of the silicon nitride layer until exposing the surface of the P-well 12 so as to form a spacer 28 on each lateral side of the gate 26. Next, an ion implantation process is performed by utilizing the gate 26 and the spacers 28 as hard masks to dope N-type dopants into the P-well 12 so as to form a source 16 and a drain 18 of the MOS transistor 20.

In addition, a dielectric layer 34 is deposited on the silicon substrate 10. A lithographic process, an etching process, a deposition process and a polishing process are thereon carried out to form a plurality of contact plugs 36 in the dielectric layer 34, and thereby completing the MOS transistor 20. The contact plugs 36 communicate with the source 16, the drain 18 and the gate 26 of the MOS transistor 20 respectively (the contact plug electrically connecting to the gate 26 is not shown in the drawing).

Taking the manufacturing process of the MOS transistor 20 as an example, lithographic processes are often carried out in the silicon substrate 10 over and over for forming the MOS transistor 20 and other elements. In comparison with other elements, the overlay accuracy among the STI structure 30, the gate 26 and the contact plugs 36 of the MOS transistor 20 should be smaller. Therefore, if there is a serious bias of the overlay accuracy due to the lithographic apparatus, defects usually occur in the structure of the MOS transistor 20. Please refer to FIG. 2, which is a schematic diagram showing a traditional MOS transistor having a serious bias of the overlay accuracy. As shown in FIG. 2, the contact plugs 36 are not disposed in the predetermined positions in practice due to a poor overlay accuracy of the lithographic process during the manufacture of the contact plugs 36. Unfortunately, one of the contact plugs 36 applied for controlling the source voltage electrically connects with both the source 16 and the gate 26, while another contact plugs 36 applied for controlling the drain voltage cannot electrically connect with the drain 18. Accordingly, the operation of the MOS transistor 20 is seriously affected, and the quality of the whole semiconductor chip is influenced.

However, with the shrinking dimensions of integrated circuits, strict overlay accuracy is required as well. According to reports of semiconductor manufacturing technology from International Technology Roadmap for Semiconductor (ITRS), the required overlay accuracy for 90 nanometers (nm) lowers from 3.5 nm to 3.2 nm, and the required overlay accuracy for 65 nm is about 2.3 nm. The overlay accuracy has become an important factor to the product yield. In other words, it is important to accurately measure the corresponding positions of the wafer for the manufacture. It is still a significant issue to improve the overlay accuracy and the performing efficiency of the lithographic processes.

### SUMMARY OF THE INVENTION

It is therefore the primary object of the present invention to provide a method of performing lithographic processes on a wafer in a lithographic apparatus having multiple stages so to improve the overlay accuracy and the performing efficiency of the lithographic processes.

According to one embodiment of the present invention, a method of performing lithographic processes is disclosed. First, a lithographic apparatus is provided. The lithographic apparatus includes a first wafer chuck and a second wafer chuck. Subsequently, a cassette is provided into the lithographic apparatus. The cassette includes a plurality of wafers, and each of the wafers has a wafer identification. Next, the first wafer chuck is configured for holding the wafers having odd wafer identifications, and the second wafer chuck is configured for holding the wafers having even wafer identifications. Furthermore, a first lithographic process is performed on each of the wafers in the lithographic apparatus.

From one aspect of the present invention, a method of performing lithographic processes is disclosed. First, a lithographic apparatus and a wafer are provided. The lithographic apparatus includes an orientation system, a projection system, a first wafer chuck and a second wafer chuck. Subsequently, a plurality of lithographic processes is performed on the wafer in the lithographic apparatus. Some of the lithographic processes are overlay related lithographic processes, which are overlay related to each other. The first wafer chuck holds the wafer in each of the lithographic processes.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The invention can be more fully understood by reading the following detailed description of the preferred embodiment, with reference made to the accompanying drawings as follows:

FIG. 1 is a schematic diagram showing a traditional MOS transistor;

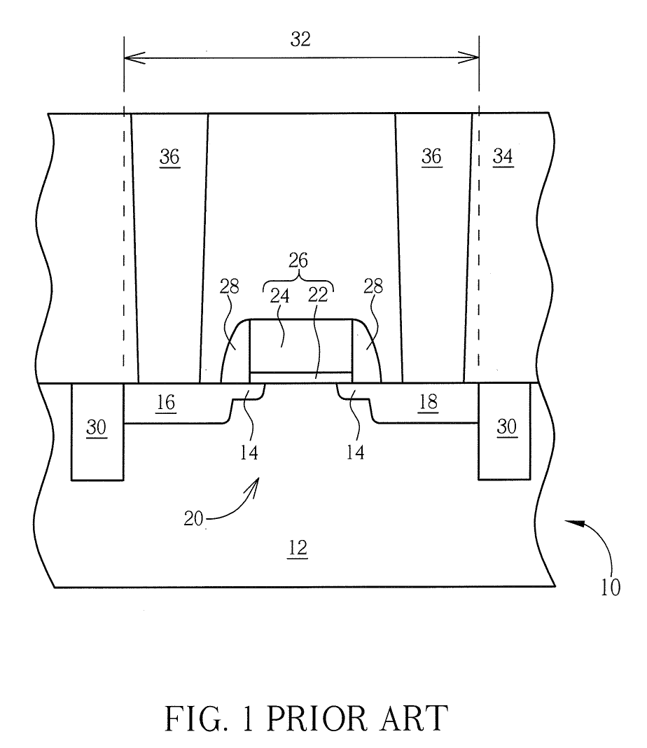

FIG. 2 is a schematic diagram showing a traditional MOS transistor having a serious bias of the overlay accuracy;

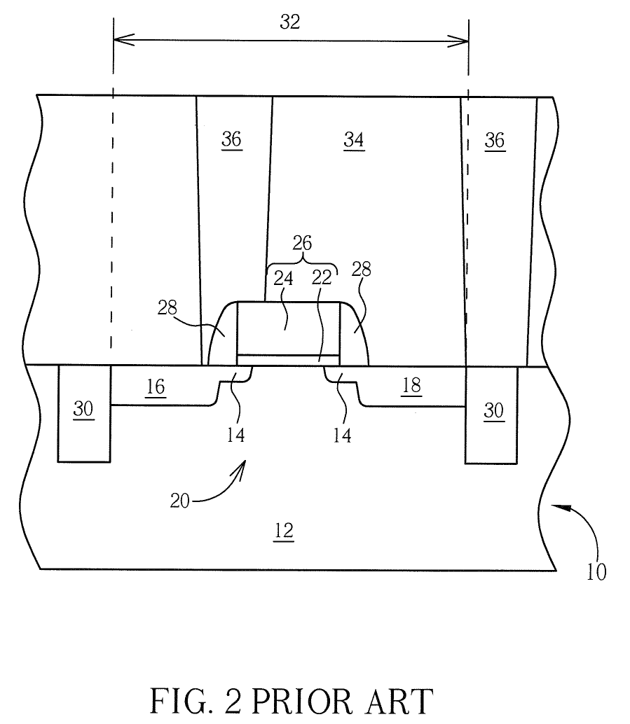

FIG. 3 is a schematic diagram illustrating a lithographic apparatus having multiple stages and the related operation;

FIG. 4 is a schematic chart illustrating a lot condition of lithographic processes performed according to the operation shown in FIG. 3;

FIG. 5 is a schematic chart illustrating a lot condition of lithographic processes in accordance with the first preferred embodiment of the present invention;

FIG. 6 is a schematic chart illustrating virtual lots condition of the second lithographic process of FIG. 5;

FIG. 7 is a flow chart illustrating the second lithographic process of FIG. 5;

FIG. 8 is a schematic chart illustrating a lot condition of lithographic processes in accordance with the second preferred embodiment of the present invention; and

FIG. 9 is a schematic chart illustrating virtual lots condition of the third lithographic process of FIG. 8.

### DETAILED DESCRIPTION

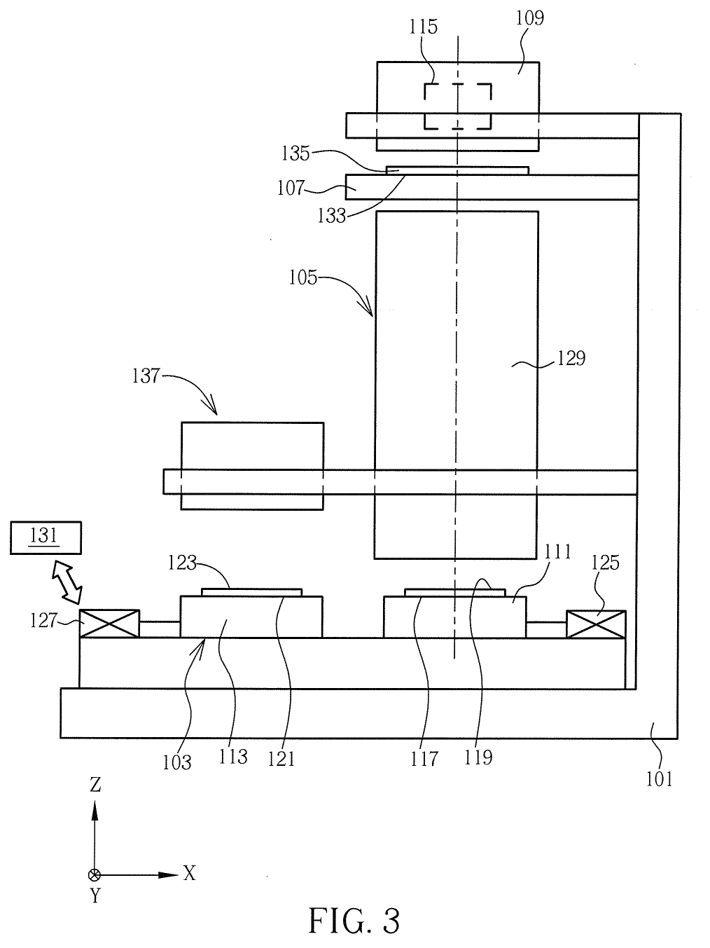

For clarity of illustration, a lithographic apparatus having multiple stages applied to the method of the present invention is first described. Please refer to FIG. 3, which is a schematic diagram illustrating a lithographic apparatus having multiple stages and the related operation, where like number numerals designate similar or the same parts, regions or elements. As FIG. 3 diagrammatically shows, the lithographic apparatus 100 is provided with a frame 101 that supports in that order, a positioning device 103, a projection system 105, an orientation system 137, a mask holder 107, and a radiation source 109. The positioning device 103 includes a first wafer chuck 111 and a second wafer chuck 113. The lithographic apparatus 100 shown in FIG. 3 can be an optical lithographic apparatus whose radiation source 109 includes a light source 115. The first wafer chuck 111 includes a support surface 117, which extends perpendicularly to the Z-direction and on which a first wafer 119 can be placed, and the second wafer chuck 113 includes a support surface 121, which extends perpendicularly to the Z-direction and on which a second wafer 123 can be placed.

The first wafer chuck 111 can be displaceable relative to the frame 101 parallel to an X-direction perpendicular to the Z-direction and parallel to a Y-direction perpendicular to the X-direction and perpendicular to the Z-direction by means of a first displacement unit 125 of the positioning device 103, while the second wafer chuck 113 is displaceable relative to the frame 101 parallel to the X-direction and parallel to the Y-direction by means of a second displacement unit 127 of the positioning device 103. The projection system 105 can be an imaging or projection system and includes an optical lens system 129 with an optical reduction factor.

The mask holder 107 includes a support surface 133 which extends perpendicularly to the Z-direction and on which a mask 135 can be placed. The mask 135 includes a pattern or a sub-pattern of a semiconductor integrated circuit. During operation, a light beam originating from the light source 115 is guided through the mask 135 and focused on the first wafer 119 by means of the lens system 29, so that the pattern present on the mask 135 is imaged on a reduced scale on the first wafer 119. The first wafer 119 includes a large number of individual fields, such as individual dies, on which identical semiconductor circuits are provided. The fields of the first wafer 119 are consecutively exposed through the mask 135 for this purpose. During the exposure of an individual field of the first wafer 119, the first wafer 119 and the mask 135 are in fixed positions relative to the projection system 105, whereas after the exposure of an individual field, a next field is brought into position relative to the projection system 105 each time in that the first wafer chuck 111 is displaced parallel to the X-direction and/or parallel to the Y-direction by the first displacement unit 125.

This process is repeated a number of times, with a different mask each time, so that complicated integrated semiconductor circuits with a layered structure are manufactured. The integrated semiconductor circuits to be manufactured by means of the lithographic apparatus 100 have a structure with detail dimensions which lie in the sub-micron range. Since the first wafer 119 is exposed consecutively through a plurality of different deposition processes, a plurality of different lithographic processes, and a plurality of different etching processes, the pattern present on the masks should be imaged on the first wafer 119 with an overlay accuracy which also lies in the sub-micron range, or even in the nanometer range.

A batch of semiconductor substrates, such as wafers, under manufacture is consecutively exposed through the mask 135 in the lithographic apparatus 100 during the lithographic process. Subsequently, said batch is consecutively exposed through a next mask. This process is repeated a number of times, each time with another mask. The wafers to be exposed are present in a magazine or a cassette from which the wafers are transported consecutively into a measuring position of the orientation system 137 by means of a transport mechanism. Said magazine and said transport mechanism, which are both of a kind usual and known per se, are not shown in FIG. 3 for simplicity's sake, and the units shown in FIG. 3 are skeleton.

In the state of the lithographic apparatus 100 as shown in FIG. 3, the first wafer chuck 111 is in an operational position of the projection system 105, in which the first wafer 119 placed on the first wafer chuck 111 can be irradiated by the radiation source 109 through the projection system 105. In the meantime, the second wafer chuck 113 is in said measuring position of the orientation system 137, in which a position of the second wafer 123 placed on the second wafer chuck 113 relative to the second wafer chuck 113 can be measured in directions parallel to the X-direction and parallel to the Y-direction by means of an optical position measuring unit 37 of the lithographic apparatus 100, and in which the second wafer 123 is positioned with respect to the second wafer chuck 113 with a predetermined accuracy by means of said transport mechanism.

As FIG. 3 shows, the optical orientation system 137 is also fastened to the frame 101. After the exposure of the first wafer 119 has been completed, the first wafer chuck 111 is displaced by the positioning device 103 in a manner to be further explained below from the operational position into the measuring position, from whence the first wafer 119 is returned to the magazine by said transport mechanism. Simultaneously, the second wafer 123 is displaced from the measuring position into the operational position by the positioning device 103 in a manner to be further explained below.

Since the position of the second wafer 123 relative to the second wafer chuck 113 has already been measured in the measuring position, a comparatively simple measurement of the position of the second wafer chuck 113 relative to the frame 101 and the projection system 105 can suffice in the operational position. Measuring and positioning a wafer relative to a wafer chuck requires comparatively much time, so that the use of the positioning device 103 according to the invention with the two wafer chucks 111 and 113 achieves a considerable increase in the manufacturing output compared with a lithographic apparatus having only one wafer chuck.

Therefore, the first wafer 119 should be positioned relative to the projection system 105 with a comparable overlay accuracy between certain lithographic processes, such as two consecutive lithographic processes, or lithographic processes for forming a shallow trench isolation pattern, a gate pattern and a contact plug pattern. Those lithographic processes needing certain overlay accuracies can be named overlay related lithographic processes. Accordingly, high requirements are imposed on the overlay related lithographic processes in the lithographic apparatus 100. Otherwise, the circuits, elements, or devices formed on the first wafer 119 might be damaged. However, the first wafer chuck 111 and the second wafer chuck 113 are still two individual mechanisms. The first wafer chuck 111 and the second wafer chuck 113 are not two identical elements in practice, so there are still some unavoidable differences, such as different mechanical accuracies, between the first wafer chuck 111 and the second wafer chuck 113, and the operating conditions may not be the same for the first wafer chuck 111 and for the second wafer chuck 113. In other words, inaccuracies exist between the processes or steps performed through the first wafer chuck 111 and the processes or steps performed through the second wafer chuck 113 due to the unavoidable differences between the first wafer chuck 111 and the second wafer chuck 113. As a result, the overlay accuracy between two patterns formed through two lithographic processes is poor, if the said lithographic processes are performed through the first wafer chuck 111 and the second wafer chuck 113 respectively. Thus, there is a poor overlay accuracy between elements or layers formed according to the two patterns.

It is noteworthy that because the acceptable overlay inaccuracies among the STI structure, the gate and the contact plugs of a MOS transistor are usually smaller than 25 nm, the overlay inaccuracy caused by the different lithographic apparatuses or different wafer chucks is often larger than the said acceptable overlay inaccuracies for the STI structure, the gate and the contact plugs, or consumes most of the said acceptable overlay inaccuracies. As a result, it is especially important for the overlay related lithographic processes to improve their overlay inaccuracy.

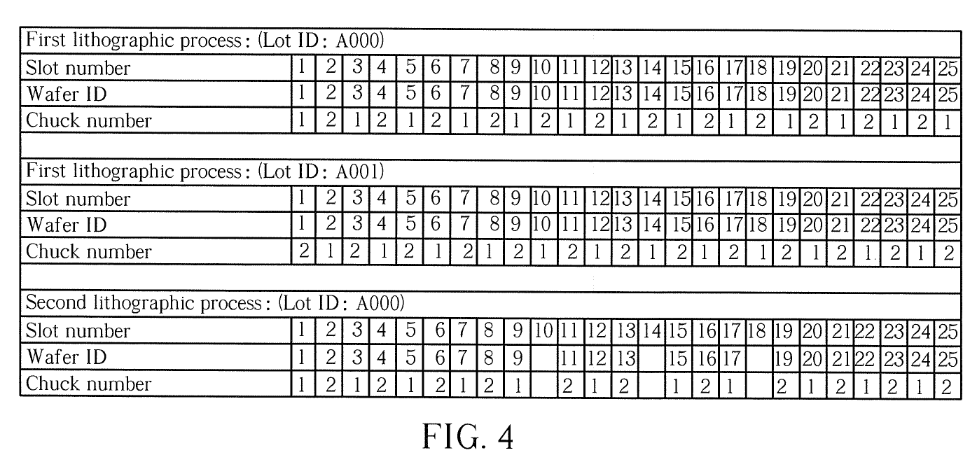

Please refer to FIG. 4, which is a schematic chart illustrating a lot condition of lithographic processes performed according to the operation shown in FIG. 3. As shown in FIG. 4, a cassette is provided into the lithographic apparatus 100 for a first lithographic process. The cassette has twenty-five slots, and each of the slots has a slot number. During the first lithographic process, each of the slots includes a wafer therein, and each of the wafers has a wafer identification. All wafers included in one cassette can be defined as one lot of wafers or one batch of wafers. For example, the wafers first provided in FIG. 4 have a lot identification (lot ID) of A000.

The lithographic apparatus 100 processes the wafers in turn through the first wafer chuck 111 and the second wafer chuck 113 alternately according to the arranged order of the wafers. Therefore, after the first wafer chuck 111 supports the wafer having the wafer ID of number one in the lot A000, wafers having the wafer identifications of number two, three, four . . . and twenty-five are supported in turn by the first wafer chuck 111 and the second wafer chuck 113 alternately until all wafers in this lot A000 have undergone the first lithographic process.

Thereafter, another full cassette having a lot ID of A001 is provided into the lithographic apparatus 100 for the first lithographic process. Since the lithographic apparatus 100 processes the wafers in turn through the first wafer chuck 111 and the second wafer chuck 113 alternately according to the arranged order of the wafers, and the wafer having the wafer ID of number one in the lot A002 is subsequent to the wafer having the wafer ID of number twenty-five in the lot A000, after the first wafer chuck 111 supports the wafer having the wafer ID of number twenty-five in the lot A000, wafers having the wafer identifications of number one, two, three, four . . . and twenty-five in the lot A001 are supported in turn by the first wafer chuck 111 and the second wafer chuck 113 alternately until all wafers n the lot A001 have undergone the first lithographic process.

As a result, it is uncertain which wafer chuck supports the wafer having the wafer ID of number one in the first lithographic process. Accordingly, the wafers are supported by a different wafer chuck from the wafer chuck used in other lithographic processes due to the lot order, so the overlay accuracy between the layers patterned by the different lithographic process is decreased.

On other hand, the wafers in the lot A000 are transferred to other apparatuses for at least a semiconductor process (not shown in the drawing), such as an etching process, a deposition process, and/or a photoresist coating process after the first lithographic process. Next, the wafers in this lot A001 are transferred to the lithographic apparatus 100 for a second lithographic process. Some of the wafers may be eliminated through inspections, such as an after development inspection (ADI) or an after etching inspection (AEI), or some of the wafers may be removed from the cassette for other reasons between the first lithographic process and the second lithographic process. As a result, some of the slots include no wafers therein, and the cassette is partially filled. As shown in FIG. 4, the slots having the slot number of number 10, 14 and 18 in the lot A000 include no wafer therein (lack of wafer) during the second lithographic process. As the above mentioned, the lithographic apparatus 100 process the wafers in turn through the first wafer chuck 111 and the second wafer chuck 113 alternately according to the arranged order of the wafers. The lithographic apparatus 100 does not distinguish the wafers according to their wafer identifications, so the lithographic apparatus 100 does not control the wafer chucks by distinguishing the individual wafer identification. Accordingly, after the first wafer chuck 111 is assigned to support the wafer having the wafer ID of number nine in the lot A000, the wafer having the wafer ID of number eleven in the lot A000 is therefore supported by the second wafer chuck 113 in the second lithographic process. Similarly, after the first wafer chuck 111 is assigned to support the wafer having the wafer ID of number seventeen, the wafer having the wafer ID of number nineteen is therefore supported by the second wafer chuck 113 in the second lithographic process. As a result, the wafers having the wafer identifications of number 11-13 and 9-25 in the lot A000 are supported by a wafer chuck, which is different from the wafer chuck used in the first lithographic process, during the second lithographic process, so the overlay accuracy between the layers patterned by the first lithographic process and the second lithographic process is decreased.

Therefore, the present invention further provides a method of performing lithographic processes to improve the overlay performance. According to the operation, the present invention can make a specific wafer chuck support a specific wafer during overlay related lithographic processes, which require a high overlay accuracy. For instance, if a high overlay accuracy is required among a STI structure, contact plugs and a gate of a MOS transistor, the present invention can make a specific wafer chuck support a specific wafer during the lithographic processes of forming these three elements. In addition, the method of the present invention can also be applied to the patterning processes for two successive layers on the semiconductor substrate.

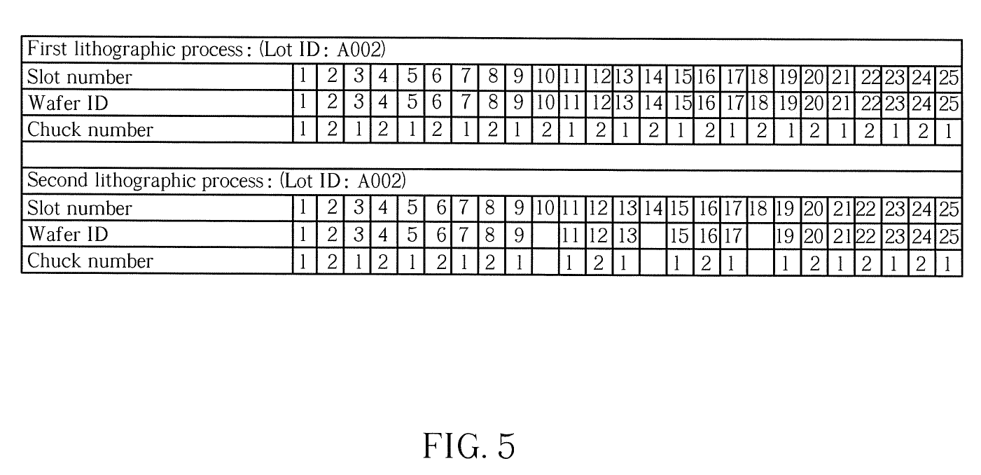

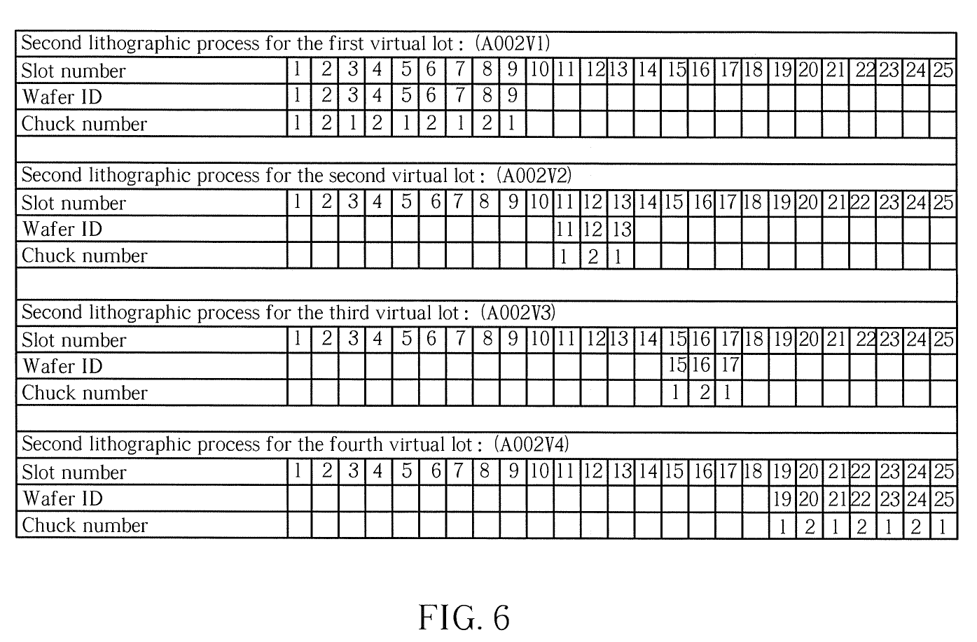

Please refer to FIG. 5 and FIG. 6. FIG. 5 is a schematic chart illustrating a lot condition of lithographic processes in accordance with the first preferred embodiment of the present invention, and FIG. 6 is a schematic chart illustrating virtual lots condition of the second lithographic process of FIG. 5. As shown in FIG. 5 and FIG. 6, a cassette is first provided into the lithographic apparatus 100 for a first lithographic process. The cassette has twenty-five slots, and each of the slots has a slot number. During the first lithographic process, each of the slots includes a wafer therein, and each of the wafers has a wafer identification. All wafers included in one cassette can be defined as one lot of wafers or one batch of wafers. For example, the wafers provided in FIG. 5 have a lot ID of A002.

The lithographic apparatus 100 further includes a controlling system (as shown in FIG. 3) 131, such as a computer program. The controlling system 131 has a functionality of assigning a specific wafer chuck to support the first treated wafer in a lot. The controlling system 131 is first configured before the lithographic processes are performed.

The first wafer chuck 111 is configured for holding the first treated wafer in a lot, if the first treated wafer has an odd wafer identification in the controlling system 131; and the second wafer chuck 113 is configured for holding the first treated wafer in a lot, if the first treated wafer has an even wafer identification in the controlling system 131.

The lithographic apparatus 100 processes the wafers in turn by utilizing the first wafer chuck 111 and the second wafer chuck 113 alternately according to the arranged order of the wafers. Therefore, the wafer having the wafer ID of number one is defined as the first treated wafer of this lot A002. For example, after the first wafer chuck 111 is assigned to support the wafer having the wafer ID of number one by the controlling system 131, wafers having the wafer identifications of number two, three, four . . . and twenty-five are supported in turn by the first wafer chuck 111 and the second wafer chuck 113 alternately until all wafers in this lot have undergone the first lithographic process.

Subsequently, the wafers in this lot A002 are transferred to other apparatuses for at least a semiconductor process (not shown in the drawing), such as an etching process, a deposition process, and/or a photoresist coating process. Thereafter, the wafers in this lot A002 are transferred to the lithographic apparatus 100 for a second lithographic process. Some of the wafers may be eliminated through inspections, such as an ADI or an AEI, or some of the wafers may be removed from the cassette for other reasons between the first lithographic process and the second lithographic process. As a result, some of the lots include no wafers therein, and the cassette is partially filled. As shown in FIG. 5, the slots having the slot number of number 10, 14 and 18 include no wafer therein (lack of wafer) during the second lithographic process.

In order to make a specific wafer chuck support a specific wafer, the wafers contained in one cassette can be divided into at least two virtual lots nominally in the controlling system 131. For instance, since the slots having the slot number of number 10, 14 and 18 include no wafer, the wafers contained in one cassette can be divided into four virtual lots nominally. The first virtual lot A002V1 includes the wafers having the wafer identifications of number 1-9, the second virtual lot A002V2 includes the wafers having the wafer identifications of number 11-13, the third virtual lot A002V3 includes the wafers having the wafer identifications of number 15-17, and the fourth virtual lot A002V4 includes the wafers having the wafer identifications of number 19-25. The wafer identifications of the wafers and the slot numbers of the slots are successive in each slot. In other words, every slot includes a wafer in each of the virtual lots.

Since the lithographic apparatus 100 processes the wafers in turn by utilizing the first wafer chuck 111 and the second wafer chuck 113 alternately according to the arranged order of the wafers, the wafers having the wafer identifications of number 1, 11, 15 and 19 are defined as the first treated wafers of the first virtual lot A002V1, the second virtual lot A002V2 the third virtual lot A002V3 and the fourth virtual lot A002V4, respectively. For each of the virtual lots, the controlling system 131 controls the first wafer chuck 111 to hold the first treated wafers, if the first treated wafers have odd wafer identifications; the controlling system 131 controls the second wafer chuck 113 to hold the first treated wafers, if the first treated wafers have even wafer identifications. Thus, all of the wafers having odd wafer identifications are processed through the first wafer chuck 111 in the first and second lithographic processes, and all of the wafers having even wafer identifications are processed through the second wafer chuck 113 in the first and second lithographic processes. Accordingly, wafers processed in the present invention have better overlay accuracies.

For instance, after the first wafer chuck 111 is assigned to support the wafer having the wafer ID of number 9, the wafers having the wafer identifications of number 11-13 are treated as another lot (the second virtual lot) of wafers. Since the first treated wafer of the second virtual lot (the wafer having the wafer ID of number 11) has an odd wafer identification, the first wafer chuck is configured for holding the wafer having the wafer ID of number 11.

Because the lithographic apparatus 100 processes the wafers in turn through the first wafer chuck 111 and the second wafer chuck 113 alternately according to the arranged order of the wafers, it is preferable to sort the wafers according to the wafer identifications and the slot numbers before providing the cassette into the lithographic apparatus for overlay related lithographic processes. In such a manner, each of the wafers can be disposed in the corresponding slots during the overlay related lithographic processes.

It is noteworthy that the wafer identifications and the slot numbers of the present invention should not be limited to the first preferred embodiment, and the wafer identifications can be different from the slot numbers. As long as the critical wafer can be disposed in the corresponding slot, variations to the identifications and the numbers, as are well known to those of ordinary skill in this art, do not alter the spirit of the present invention.

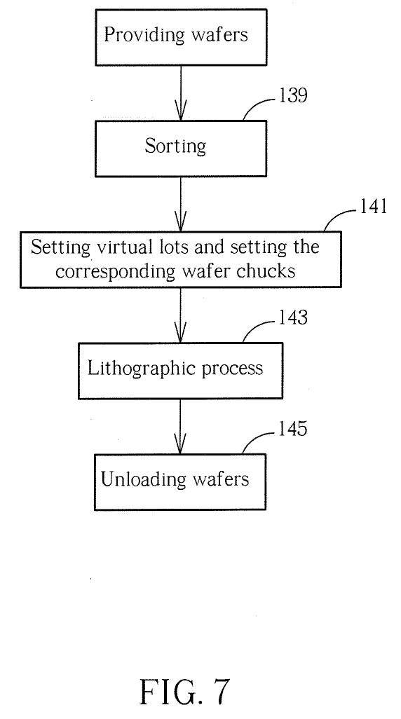

Please refer to FIG. 7, which is a flow chart illustrating the second lithographic process of FIG. 5. As shown in FIG. 7, the wafers of the cassette are first sorted according to the wafer identifications and the slot numbers in the controlling system 131 (step 139). Substantially, the virtual lots are configured according to the lack condition of wafers, and the corresponding wafer chucks are therefore configured in the controlling system 131 (step 141). Next, a second lithographic process is carried out on each of the wafers according to the configured virtual lots and the configured wafer chucks (step 143). Furthermore, the wafers are unloaded (step 145), and thereafter undergo other semiconductor processes.

It deserves to be mentioned that the controlling system 131 can be configured or the configuration of the controlling system 131 can be changed before or after any step in practice. For instance, if the lack condition in the lot has been known, the virtual lots can be configured in the controlling system 131 before the sorting treatment. In addition, the step of configuring the first wafer chuck 111 for holding the wafers having odd wafer identifications, and configuring the second wafer chuck 113 for holding the wafers having even wafer identifications can be carried out in any step in practice, such as before or after the sorting treatment. For example, if this configuring step is performed before the first lithographic process of the present invention, the lithographic apparatus 100 can follow the configuration of the controlling system 131 in the subsequent second lithographic process without further amendment. In such a manner, it is unnecessary for the following lithographic process to include a step of configuring the wafer chucks.

Because the virtual lots are utilized for performing lithographic processes, the present invention can easily make a specific wafer chuck automatically support a specific wafer according to the configuration of the controlling system 131. The present invention can improve the overlay accuracy and the yield of the lithographic processes without taking extra time, processes, or energy, and overcome the differences between wafer chucks, such as different mechanical accuracies or different operations. Furthermore, since the lithographic processes can be performed by a systematized procedure and an automated controlling system 131, the method of the present invention can be popularly applied to various lithographic processes, and is not limited by types of the lithographic processes, operation of the apparatus, types of the cassettes, arrangements of the wafers or materials of the wafers. The present invention can make a specific wafer chuck automatically support a specific wafer in overlay related lithographic processes, no matter if the cassette is filled or partially filled, no matter which slot includes no wafer, and no matter which lot the wafer belongs to.

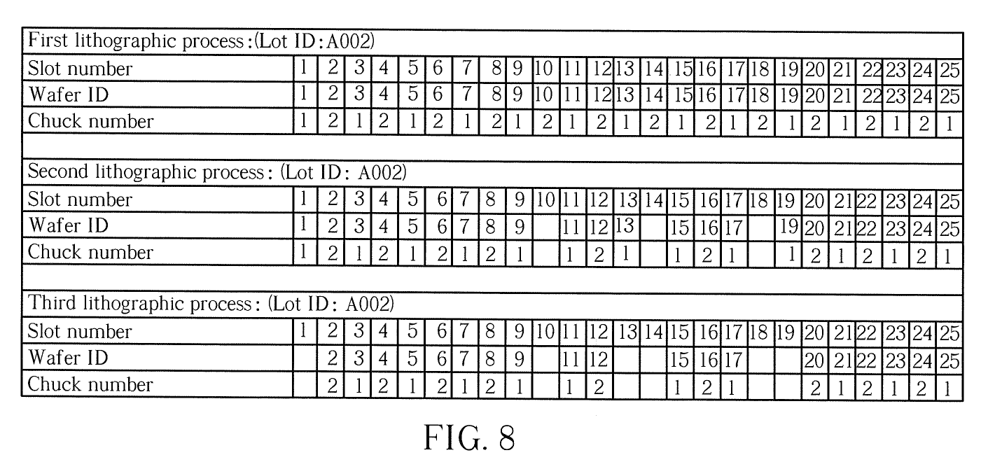

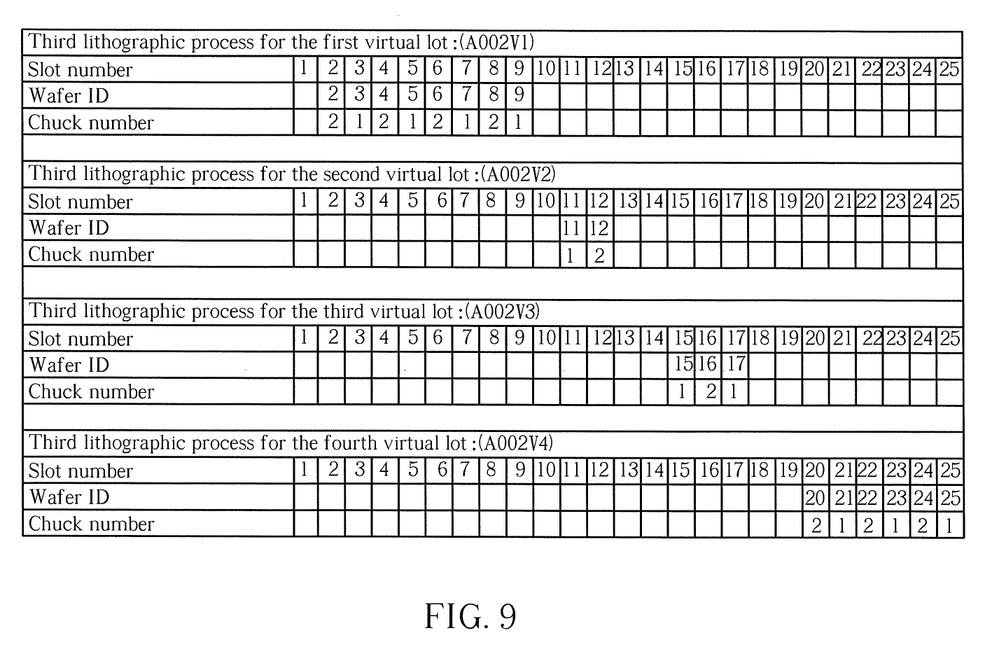

Please refer to FIG. 8 and FIG. 9. FIG. 8 is a schematic chart illustrating a lot condition of lithographic processes in accordance with the second preferred embodiment of the present invention, and FIG. 9 is a schematic chart illustrating virtual lots condition of the third lithographic process of FIG. 8. As shown in FIG. 8 and FIG. 9, the wafers in this lot A002 are transferred to other apparatuses for at least a semiconductor process (not shown in the drawing), such as an etching process, a deposition process, and/or a photoresist coating process after the second lithographic process. Thereafter, the wafers in this lot A002 are transferred to the lithographic apparatus 100 for a third lithographic process. Some of the wafers may be eliminated through at least an inspection, or some of the wafers may be removed from the cassette for other reasons between the second lithographic process and the third lithographic process. As a result, more slots include no wafers therein. As shown in FIG. 8, the slots having the slot number of number 1, 10, 13, 14, 18 and 19 include no wafer therein (lack of wafer) during the third lithographic process.

Subsequently, the wafers contained in the cassette can be divided into four virtual lots nominally in the controlling system 131, so every slot includes a wafer in each of the virtual lots. As shown in FIG. 9, the first virtual lot A002V1 includes the wafers having the wafer identifications of number 2-9, the second virtual lot A002V2 includes the wafers having the wafer identifications of number 11-12, the third virtual lot A002V3 includes the wafers having the wafer identifications of number 15-17, and the fourth virtual lot A002V4 includes the wafers having the wafer identifications of number 20-25.

Since the lithographic apparatus 100 processes the wafers in turn by utilizing the first wafer chuck 111 and the second wafer chuck 113 alternately according to the arranged order of the wafers, the wafers having the wafer identifications of number 2, 11, 15 and 20 are defined as the first treated wafers of the first virtual lot A002V1, the second virtual lot A002V2 the third virtual lot A002V3 and the fourth virtual lot A002V4, respectively. According to the wafer identifications of the first treated wafers, the second wafer chuck 113, the first wafer chuck 111, the first wafer chuck 111 and the second wafer chuck 113 are assigned to support the first treated wafers of the first, second, third and fourth virtual lots, respectively.

According to the spirit of the present invention, the present invention can make a specific lithographic device automatically support a specific wafer by a systematized procedure and an automated controlling system. Thus, the assigned lithographic device should not be limited to wafer chucks. In other embodiments of the present invention, at least two lithographic devices, which can operate simultaneously, and at least a controlling system can be included. The controlling system can assign a specific lithographic device to support a specific wafer. The said lithographic devices can be lithographic apparatuses or equipments including individual wafer chucks, frames, orientation systems or projection systems. As a result, the present invention can improve the overlay accuracy and the yield of the lithographic processes without taking extra time, processes, or energy. Furthermore, the concept of the present invention can be applied to other kinds of processes, so that a specific semiconductor device can be assigned to support a specific wafer by a systematized procedure and an automated controlling system in other kinds of processes, and the inaccuracy caused by different processing devices can be therefore reduced.

In sum, the overlay accuracies of the overlay related lithographic processes forming a shallow trench isolation pattern, a gate pattern and a contact plug pattern should be more exact. However, the overlay inaccuracy caused by the different lithographic apparatuses or different wafer chucks is often larger than the said acceptable overlay inaccuracies for those element. Since the virtual lots are applied in this method to assign a specific wafer chuck to support a specific wafer for those overlay related lithographic processes, the overlay accuracies of the overlay related lithographic processes can be increased, and the yield of the semiconductor processes is therefore improved.

Those skilled in the art will readily observe that numerous modifications and alterations of the device and method may be made while retaining the teachings of the invention.

What is claimed is:

1. A method of performing lithographic processes, comprising:
providing a lithographic apparatus, the lithographic apparatus comprising a first wafer chuck and a second wafer chuck;
providing a cassette into the lithographic apparatus, the cassette comprising a plurality of wafers, each of the wafers having a wafer identification;
configuring the first wafer chuck for holding the wafers having odd wafer identifications, and configuring the second wafer chuck for holding the wafers having even wafer identifications; and
performing a first lithographic process on each of the wafers in the lithographic apparatus.

2. The method of claim 1, wherein the cassette comprises a plurality of slots, and the wafers are disposed in the slots.

3. The method of claim 2, wherein each of the slots comprises a slot number.

4. The method of claim 3, further comprising sorting the wafers according to the wafer identifications and the slot numbers before providing the cassette into the lithographic apparatus, so each of the wafers is disposed in the corresponding slots.

5. The method of claim 2, wherein at least one of the slots comprises no wafers.

6. The method of claim 1, wherein the lithographic apparatus comprises an orientation system and a projection system.

7. The method of claim 6, wherein each of the first lithographic processes comprises an orienting step and a projecting step, and the first wafer chuck is in the projection system for the projecting step while the second wafer chuck is in the orientation system for the orienting step.

8. The method of claim 6, wherein each of the first lithographic processes comprises an orienting step and a projecting step, and the first wafer chuck is in the orientation system for the orienting step while the second wafer chuck is in the projection system for the projecting step.

9. The method of claim 3, further comprising performing a second lithographic process on each of the wafers in the lithographic apparatus after the first lithographic process, wherein the first wafer chuck holds the wafers having odd wafer identifications, and the second wafer chuck holds the wafers having even wafer identifications.

10. The method of claim 1, wherein the wafers contained in the cassette are divided into at least two virtual lots.

11. The method of claim 10, wherein the wafers, which have the minimum wafer identifications in each of the virtual lots, are defined as first treated wafers of the corresponding virtual lots.

12. The method of claim 11, wherein the lithographic apparatus further comprises a controlling system, and the step of configuring the first wafer chuck and the second wafer chuck is performed by configuring the controlling system.

13. The method of claim 12, wherein the controlling system controls the first wafer chuck to hold the first treated wafers having odd wafer identifications, and the first wafer chuck and the second wafer chuck hold the wafers alternately.

14. The method of claim 12, wherein the controlling system controls the second wafer chuck to hold the first treated wafers having even wafer identifications, and the first wafer chuck and the second wafer chuck hold the wafers alternately.

15. A method of performing lithographic processes, comprising:
providing a lithographic apparatus and a wafer, the lithographic apparatus comprising an orientation system, a projection system, a first wafer chuck and a second wafer chuck; and
performing a plurality of lithographic processes on the wafer in the lithographic apparatus, some of the lithographic processes being overlay related lithographic processes, which are overlay related to each other, and the first wafer chuck holding the wafer in each of the overlay related lithographic processes.

16. The method of claim 15, wherein each of the overlay related lithographic processes comprises an orienting step and a projecting step.

17. The method of claim 16, wherein the first wafer chuck is in the projection system for the projecting step while the second wafer chuck is in the orientation system for the orienting step.

18. The method of claim 16, wherein the first wafer chuck is in the orientation system for the orienting step while the second wafer chuck is in the projection system for the projecting step.

19. The method of claim 15, wherein the overlay related lithographic processes form a shallow trench isolation pattern, a gate pattern and a contact plug pattern.

20. The method of claim 15, wherein the wafers comprises two stacked material layers, and the overlay related lithographic processes form two patterns in the two stacked material layers respectively.
